(19) United States
(12) Patent Application Publication
(10) Pub. No.: US 2015/0179854 A1
(43) Pub. Date: Jun. 25, 2015

(54) METHOD OF PACKAGING BALL LENS OF SOLAR COLLECTOR AND STRUCTURE THEREOF

(71) Applicant: ATOMIC ENERGY COUNCIL - INSTITUTE OF NUCLEAR ENERGY RESEARCH, Taoyuan County (TW)

(72) Inventors: YUEH-MU LEE, TAOYUAN COUNTY (TW); ZUN-HAO SHIH, TAOYUAN COUNTY (TW); YI-PING LIANG, TAOYUAN COUNTY (TW); HWA-YUH SHIN, TAOYUAN COUNTY (TW); HWEN-FEN HONG, TAOYUAN COUNTY (TW)

(73) Assignee: ATOMIC ENERGY COUNCIL - INSTITUTE OF NUCLEAR ENERGY RESEARCH, Taoyuan County (TW)

(21) Appl. No.: 14/133,937

(22) Filed: Dec. 19, 2013

(51) Int. Cl. H01L 31/052; H01L 31/18

(52) U.S. Cl. CPC H01L 31/0524; H01L 31/18

(57) ABSTRACT

A method of packaging ball lends of a solar collector contains step of coating optical clear adhesives on colloid layers twice, and the optical clear adhesives are solidified so that a solar cell, plural gold wires, and an electric circuit are packaged, thus eliminating use of a conventional support component, lowering weight of the solar collector, and simplifying the solar collector. Moreover, a dam is applied to absorb stray light so as to enhance light absorption of the solar cell and working efficiency of the solar collector.

### FIELD OF THE INVENTION

The present invent relates to a method of packing a solar collector and a structure thereof, and more particularly to a method of packing ball lens of a solar collector and a structure thereof which applies the ball lens as a secondary optical element and eliminates a support component for supporting the ball lens.

### BACKGROUND OF THE INVENTION

Solar power is collected by a solar cell on which sunlight is illuminated. To enhance power efficiency, condenser lens is fixed in a concentrated solar module so as to collect light energy effectively. The concentrated solar collector module contains a solar collector for collecting sunlight and is produced automatically, wherein at least one collar cell is mounted in the solar collector, and its size is decreased to save production material and cost.

For example, a solar cell is applied to match with a secondary optical element, such as a ball lens, to reduce a light focus point, increase sunlight irradiating angle, and shorten focal distance. However, a conventional method of fixing the ball lens cannot obtain these purposes.

As shown in FIG. 1, a conventional structure of fixing a ball lens contains a substrate 10 disposed in a concentrated solar module, an electric circuit 12 arranged on the base 10, wherein the electric circuit has a plurality of electricity conducting blocks, and one of the plurality of electricity conducting blocks has a solar cell 11 disposed thereon and electrically connected with other electricity conducting blocks through at least one gold wire 13. A ball lens 3 is located above the solar cell 11 and is positioned by two fixing pads 6.

As illustrated in FIG. 2, a device of fixing ball lens contains an O-ring 7 on which a ball lens 3 is positioned. The O-ring 7 is used to replace the two fixing pads 6 and to position the ball lens 3. Nevertheless, these support components are provided in the conventional fixing structure and device, thus increasing weight and parts quantity of the solar collector module.

Due to sunlight is influenced by water vapors and suspended solids in air and condenser lens, it cannot focus effectively to generate stray light. In addition, the stray light, which does not irradiate on the ball lens, cannot be absorbed by the solar cell, thus losing working efficiency of the solar collector module.

Accordingly, weight, part quantity and simplified structure are necessary for miniaturizing concentrator solar cell module. Also, the stray light has to be collected and used to enhance working efficiency of the solar collector module.

The present invention has arisen to mitigate and/or obviate the afore-described disadvantages.

### SUMMARY OF THE INVENTION

The primary object of the present invention is to provide a method of packaging ball lens of a solar collector which contains step of coating optical clear adhesives on colloid layers twice, and the optical clear adhesives are solidified so that a solar cell, plural gold wires, and an electric circuit are packaged, thereafter optical clear adhesive is coated again to position the ball lens, such that the ball lens will not deposit downwardly to press and damage the plural gold wires.

Further object of the present invention is to provide a structure of packaging ball lens of a solar collector, which after the ball lens is positioned by ways of optical clear adhesive, a conventional support component is eliminated to lower weight of the solar collector and to decrease energy consumption resulting from chasing sun.

Another object of the present invention is to provide a structure of packaging ball lens of a solar collector which contains a dam used in step of coating optical clear adhesive in second time so that the optical clear adhesive is limited within a certain range to enhance a coating area; hence stray light, which does not irradiate on the ball lens, is guided to illuminate the solar cell so as to increase working efficiency of the solar collector.

To obtain the above objective, a method of packaging ball lens of a solar collector steps of: fixing a solar cell on a substrate; forming a first colloid layer on the substrate and covering the solar cell by using the first colloid layer; solidifying the first colloid layer; forming a second colloid layer on the first colloid layer; arranging a ball lens on the second colloid layer; and solidifying the second colloid layer.

### BRIEF DESCRIPTION OF THE DRAWINGS

FIG. 1 is a plan view showing a conventional structure of fixing a ball lens.

FIG. 2 is a perspective view showing a conventional support component (i.e., O-ring) being used to position the ball lens.

FIG. 3 is a flow chart of a method of packaging ball lens of a solar collector according to the present invention.

FIGS. 4A to 4E are a plan view showing the assembly of a structure of packaging ball lens of a solar collector according to a first embodiment of the present invention.

FIGS. 5A to 5F is a plan view showing the assembly of a structure of packaging ball lens of a solar collector according to a second embodiment of the present invention.

FIG. 6 is a perspective view showing the assembly of a fixture being applied in the structure of packaging ball lens of the solar collector according to the present invention.

FIGS. 7A and 7B are a plan view showing the structure of packaging ball lens of the solar collector being used to package a plurality of ball lens according to the present invention.

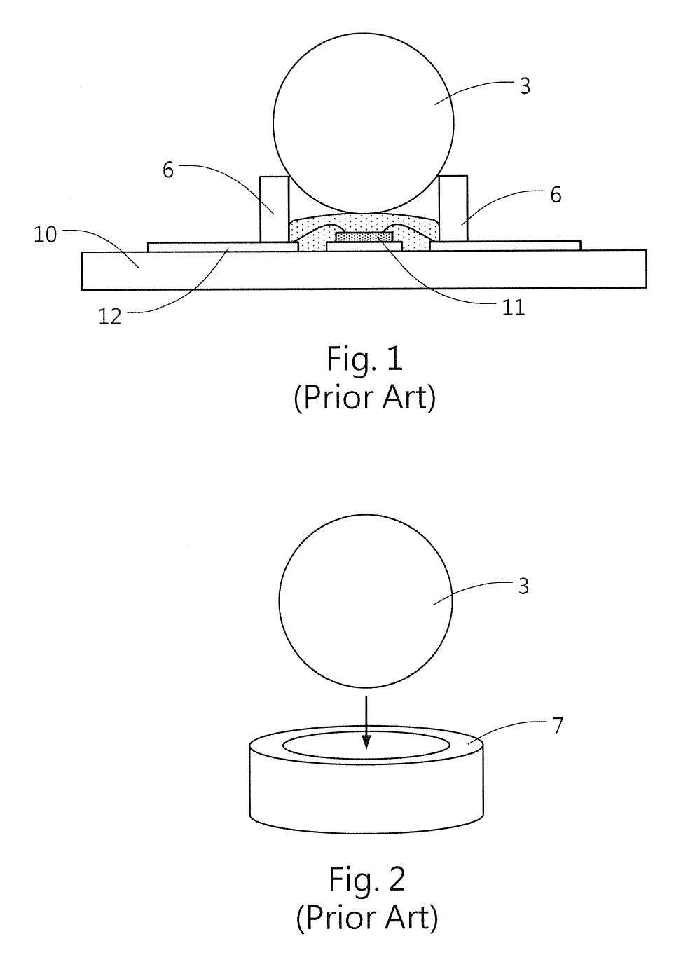

### DETAILED DESCRIPTION OF THE PREFERRED EMBODIMENTS

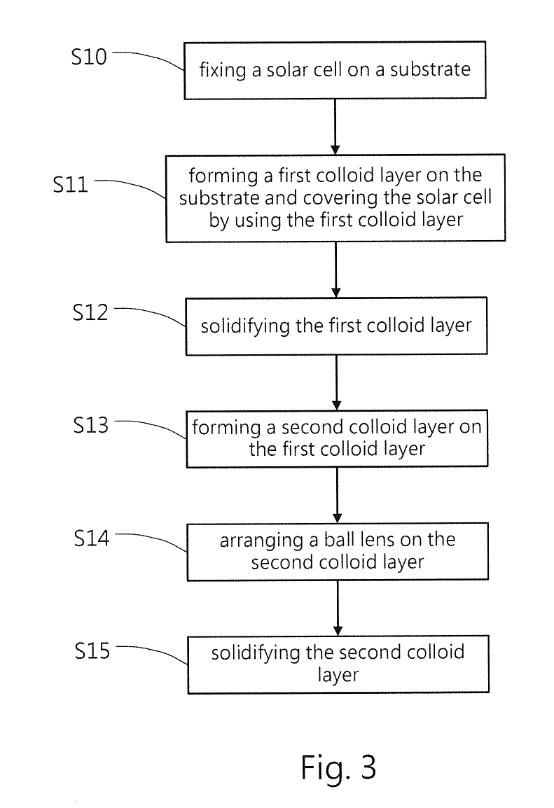

With reference to FIG. 3, a method of packaging ball lends of a solar collector according to the present invention comprises steps of:

S10: fixing a solar cell on a substrate;

S11: forming a first colloid layer on the substrate and covering the solar cell by using the first colloid layer;

S12: solidifying the first colloid layer;

S13: forming a second colloid layer on the first colloid layer;

S14: arranging a ball lens on the second colloid layer; and

S15: solidifying the second colloid layer.

After the solar cell, plural gold wires and an electric circuit, which are located below the ball lens, are packaged and solidified by the first colloid layer, the ball lens is positioned by solidifying the second colloid layer, such that the ball lens will not deposit downwardly to press and damage the plural gold wires when using one-time coating to coat the first colloidal layer and the second colloidal layer.

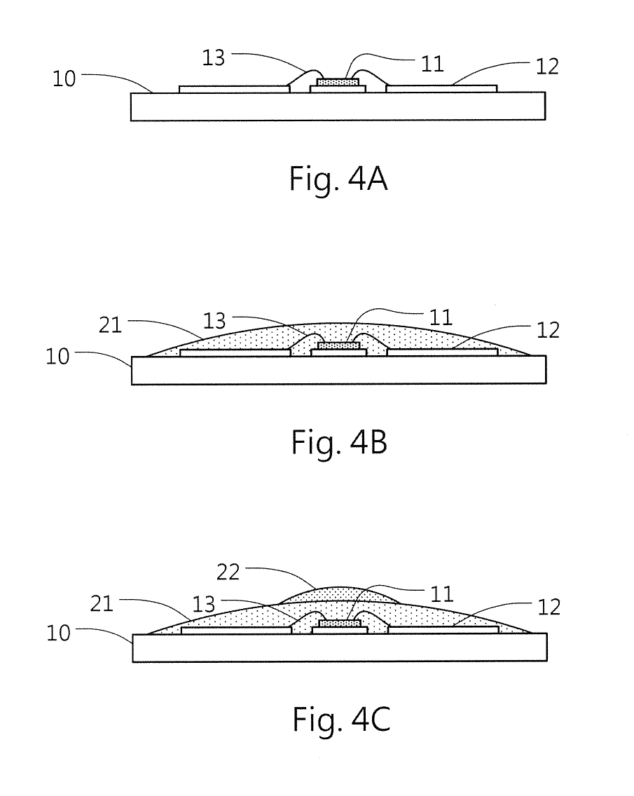

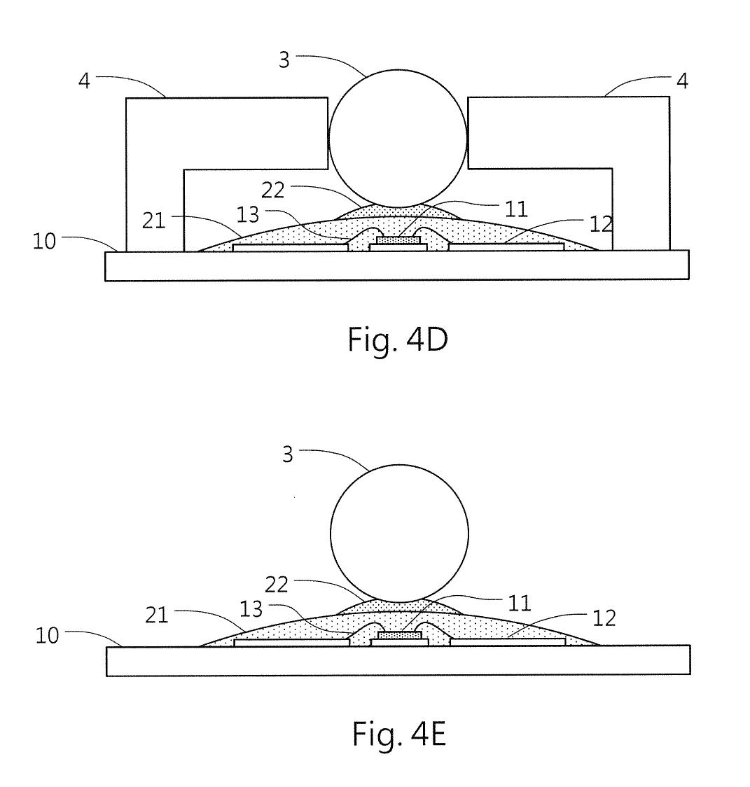

With reference to FIGS. 4A to 4E, a structure of packaging ball lends of a solar collector according to a first embodiment of the present invention comprises: a substrate 10, a solar cell H fixed on the substrate 10, an electric circuit 12 and plural gold wires 13 defined between the substrate 10 and the solar cell 11. It is to be noted that the substrate 10, the solar cell 11, the electric circuit 12 and the plural gold wires 13 are components of a solar cell collector, wherein the electric circuit includes a plurality of blocks, and the solar cell 11 is mounted on one of the plurality of blocks and is electrically connected with other blocks of the electric circuit via the plural gold wires 13.

In addition, a first colloid layer 21 is formed on the substrate 10 and has optical clear adhesive coated thereon so as to cover the solar cell 11, such that the first colloid layer 21 packages and protects the solar cell 11, the electric circuit 12, and the plural gold wires 13, thus preventing aging and corrosion of the solar cell 11, the electric circuit 12, and the plural gold wires 13. Also, the solar cell 11 can receive sunlight efficiently. It is to be noted that since the optical clear adhesive is a substance with liquidity, it solidifies after being irradiated by ultraviolet (UV) to package the solar cell 11. The optical clear adhesive can be also solidified by being placed at room temperature environment or by ways of heating means, etc.

The second colloid layer 22 has optical clear adhesive coated thereon and is applied to position a ball lens 3 above the solar cell H, so a coating amount of the optical clear adhesive of the second colloid layer 22 is less than that of the first colloid layer 21, such that the second colloid layer 22 partially covers the first colloid layer 21, and the ball lens 3 is coupled with the first colloid layer 21.

When the ball lens 3 is placed on the second colloid layer 22, and the second colloid layer 22 does not solidified, a fixture 4 is used to position the ball lens 3 auxiliary, wherein the fixture 4 includes a plurality of orifices 41 defined thereon so as to receive the ball lens 3, and a diameter of each orifice 41 is larger than that of the ball lens 3, such that when the ball lens 3 is placed into one of the plurality of orifices 41, it is positioned above the solar cell 11 by the fixture 4, and then ultraviolet (UV) irradiates and solidifies the second colloid layer 22 so that the ball lens 3 is positioned on the second colloid layer 22, thereafter the fixture 4 is removed, thus packaging the ball lens of the solar collector as shown in FIG. 4E.

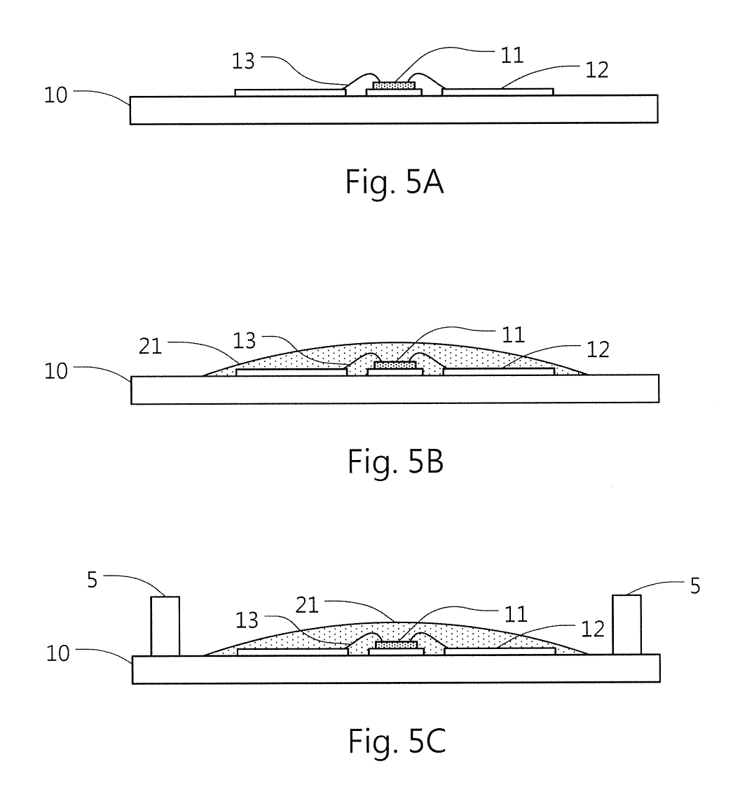

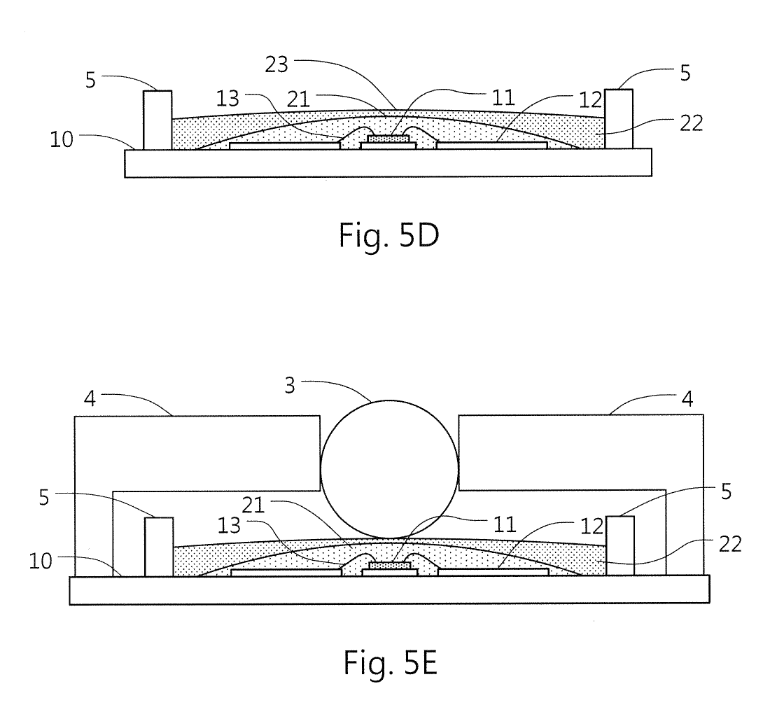

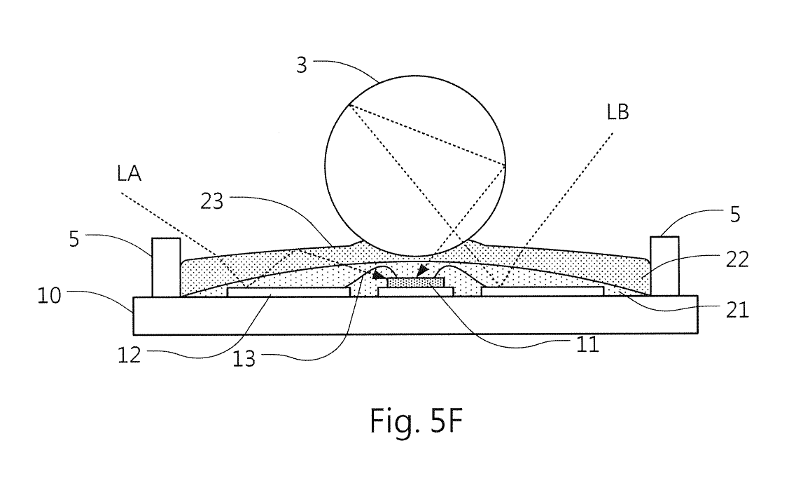

With reference to FIGS. 5A to 5F, a difference of a structure of packaging ball lends of a second embodiment from that of the first embodiment comprises: a second colloid layer 22 completely covers a first colloid layer 21, wherein a coating amount of optical clear adhesive of the second colloid layer 22 is increased; a dam 5 used for limiting the optical clear adhesive within a certain range when coating the optical clear adhesive in a second-time coating process so as to enhance a coating area of the optical clear adhesive; hence the optical clear adhesive guides stray light, which does not irradiate on the ball lens 3, to illuminate the solar cell 11, thus increasing working efficiency of the solar collector.

In this embodiment, after the first colloid layer 21 is solidified on the substrate 10, the dam 5 is placed on the substrate 10. The dam 5 surrounds the first colloid layer 21 and is made of any one of optical clear adhesive, silicone and epoxy. Taking this optical clear adhesive for example, it is pre-solidified and is placed on the substrate 10. The dam 5 is not a support component for supporting the ball lens 3 like a conventional 0-ring, and it is capable of being expanded based on an area of the second colloid layer 22 and is away from a central position of the solar collector.

After placing the dam 5, the optical clear adhesive is filled into the dam 5 to form the second colloid layer 22, such that the second colloid layer 22 covers the first colloid layer 21, and the dam 5 has a light absorbing face 23 defined therein. A fixture 4 is served to position the ball lens 3, and the second colloid layer 22 solidifies to position the ball lens 3, thereafter the fixture is removed to finish package of the ball lens of the solar collector as illustrated in FIG. 5F.

As shown in FIG. 5F, the light absorbing face 23 of the dam 5 is a surface of the second colloid layer (the first colloid layer and the second colloid layer are connected together), such that after stray lights LA, LB, which do not irradiate on the ball lens 3, enter into the light absorbing face 23, they reflect in the first colloid layer and the second colloid layer and then illuminate the solar cell 11, thus increasing sunlight exposure and working efficiency of the solar collector. It is to be noted that when an area of the light absorbing face 23 is larger than a cross-sectional area of the ball lens 3, a light absorption is enhanced.

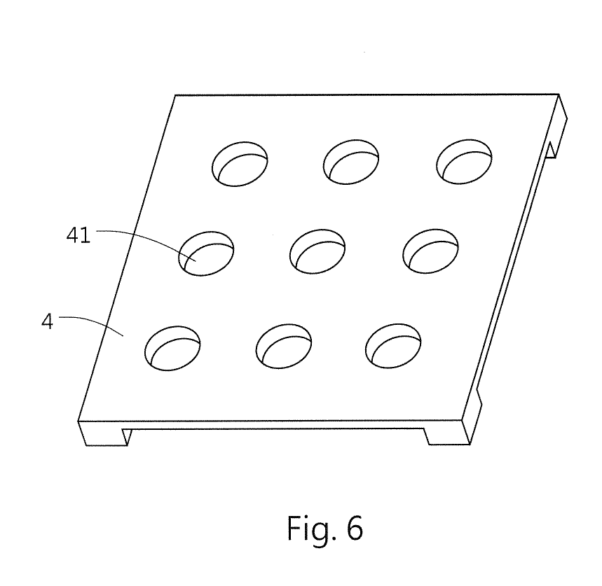

With reference to FIG. 6, the fixture 4 is made of rigid material (such as metal) and has the plurality orifices defined thereon and matching with plural ball lens, such that the fixture 4 is simplified and reusable and can be extended in an array configuration so as to package the plurality of ball lens.

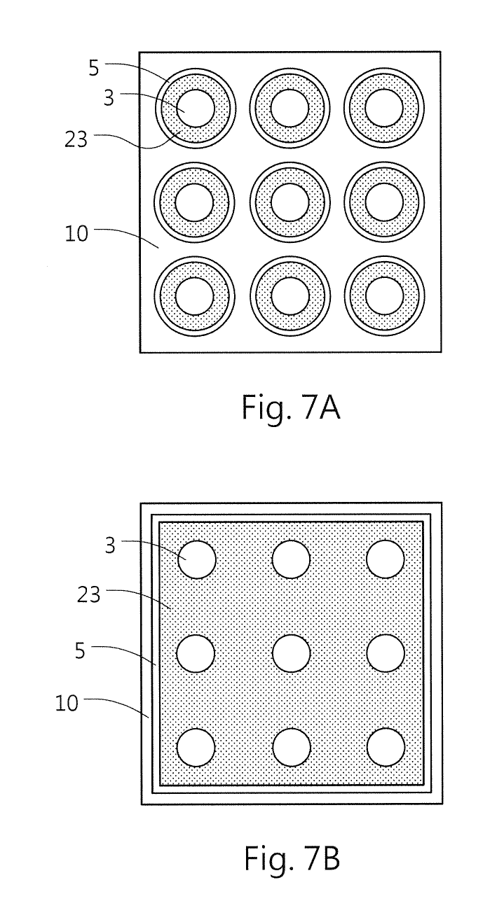

With reference to FIGS. 7A to 7B, the structure of packaging ball lends of the solar collector is used to package the plurality of ball lens simultaneously, wherein each dam 5 is in any one shape of square, circle and geometry and is applied to surround each first colloid layer (not shown), and a profile of each light absorbing face 3 corresponds to that of each dam 5. In other words, a plurality of dam 5 correspondingly surround the plural first colloid layers so that the plural light absorbing faces 23 of a plurality of solar collectors are coupled together so that stray lights are received by the plurality of solar collectors through the plural light absorbing faces 23.

Thereby, the optical clear adhesives are coated on the colloid layers twice and are solidified so that the solar cell, the plural gold wires, and the electric circuit are packaged, thus eliminating use of a conventional support component, lowering weight of the solar collector, and simplifying the solar collector. Moreover, the dam is applied to absorb stray light to enhance light absorption of the solar cell and working efficiency of the solar collector.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A method of packaging ball lends of a solar collector comprises steps of:
fixing a solar cell on a substrate;
forming a first colloid layer on the substrate and covers the solar cell by using the first colloid layer;
solidifying the first colloid layer;
forming a second colloid layer on the first colloid layer;
arranging a ball lens on the second colloid layer; and
solidifying the second colloid layer.

2. The method as claimed in claim 1, wherein the material of the first colloid layer and the second colloid layer is optical clear adhesive.

3. The method as claimed in claim 1, wherein a coating amount of the optical clear adhesive of the first colloid layer is larger than that of the second colloid layer.

4. The method as claimed in claim 1, further comprising a step of placing a dam on the substrate, before forming the second colloid layer on the first colloid layer; wherein the dam surrounds the first colloid layer.

5. The method as claimed in claim 4, wherein the second colloid layer is filled into the dam.

6. The method as claimed in claim 4, wherein the dam is made of optical clear adhesive, silicone or epoxy.

7. The method as claimed in claim 1, wherein in step of arranging the ball lens on the second colloid layer, a fixture is used to position the ball lens.

8. The method as claimed in claim 7, wherein the fixture includes a plurality of orifice defined thereon, and a diameter of each orifice is larger than that of the ball lens.

9. The method as claimed in claim 1, wherein a surface of the second colloid layer is a light absorbing face, and an area of the light absorbing face is larger than a cross-sectional area of the ball lens.

10. The method as claimed in claim 1, wherein the solar cell is connected with a plurality of gold wires, and the first colloid layer covers the gold wires.

11. A structure of packaging ball lends of a solar collector comprising:
a substrate;
a solar cell fixed on the substrate;
a first colloid layer formed on and covers the solar cell;
a second colloid layer formed on the first colloid layer; and
a ball lens arranged on the second colloid layer and positioned on the solar cell by solidifying the second colloid layer.

12. The structure as claimed in claim 11, wherein the second colloid layer partially covers the first colloid layer.

13. The structure as claimed in claim 11, wherein the second colloid layer completely covers the first colloid layer.

14. The structure as claimed in claim 13, further comprising a dam placed on an outer peripheral side of the second colloid layer.

15. The structure as claimed in claim 14, wherein a surface of the second colloid layer is a light absorbing face, and an area of the light absorbing face is larger than a cross-sectional area of the ball lens.

16. The structure as claimed in claim 11, further comprising a plurality of gold wires connected with the solar cell and covered in the first colloid layer.
